(19) United States
(12) Patent Application Publication
(10) Pub. No.: US 2025/0390618 A1
(43) Pub. Date: Dec. 25, 2025

(54) ENGINEERING A PHYSICAL SYSTEM METHOD AND SYSTEM

(71) Applicant: Siemens Industry Software Inc., Plano, TX (US)

(72) Inventor: Maria Bonner, Nürnberg (DE)

(21) Appl. No.: 18/879,803

(22) PCT Filed: Jun. 29, 2022
(86) PCT No.: PCT/IB2022/056034

§ 371 Date: Dec. 29, 2024

(51) Int. Cl. G06F 30/12; G06F 3/0482

(52) U.S. Cl. CPC G06F 30/12; G06F 3/0482

(57) ABSTRACT

For improved engineering of a physical system, a computer-implemented method includes providing a set of first engineering artifacts and a set of second engineering artifacts of engineering information of the physical system. A first annotation tree including first nodes representing the set of first engineering artifacts and a second annotation tree including second nodes representing the set of second engineering artifacts are determined. At least one ontology relating to the engineering information is provided. A respective similarity value of the respective first node and the respective second node is determined using the respective ontology. At least one of the first nodes that is related to at least one of the second nodes is determined using the respective similarity value, and a respective connector linking the respective first engineering artifact corresponding to the respective first node with the respective second engineering artifact corresponding to the related, respective second node is generated.

This application is the National Stage of International Application No. PCT/IB2022/056034, filed Jun. 29, 2022. The entire contents of this document are hereby incorporated herein by reference.

### TECHNICAL FIELD

The present disclosure is directed, in general, to electrical/electronic (E/E) systems, engineering systems, engineering management systems, systems engineering systems, and similar systems, such as computer-aided design (CAD), computer-aided manufacturing (CAM), computer-aided engineering (CAE), and electronic design automation (EDA), that are used to design, integrate, manufacture, service, and manage E/E or physical systems, such as cars, aircraft, machines, structures, and other items, including bridges, tunnels, roads, vehicles, and buildings. The present disclosure is further directed, in general, to product lifecycle management (PLM) systems, application lifecycle management (ALM) systems (e.g., for software), artifact information systems, and similar systems that are used to create, use, and manage data for products including software and artifacts and other items. The mentioned systems are collectively referred to herein as product systems. Further, the present disclosure is directed, in general, to the interplay of the mentioned engineering systems and the PLM or ALM systems.

### BACKGROUND

The present embodiments generally relate to the engineering of a physical system, especially to an improved traceability of the engineering information of the physical system.

Product systems may include stored content associated with physical systems and product lifecycle information of physical systems. Such content may include engineering information and lifecycle information of the physical system to be engineered. Such physical systems (e.g., modern E/E systems) may sometimes be characterized by a huge growth in complexity. One of the biggest challenges may be developing these complex, multi-domain systems in a coherent, integrated way, which is driving companies to evolve their E/E system development approaches to meet the market challenges of tomorrow. One challenge may be to overcome boundaries between software, electrical, electronic, and network development to provide comprehensive traceability and compliance whilst accelerating product development.

Currently, there exist product systems and solutions that support engineering a physical system. Such product systems may benefit from improvements.

### SUMMARY AND DESCRIPTION

Variously disclosed embodiments include data processing systems and methods that may be used to facilitate engineering a physical system, especially to an improved traceability of the engineering information of the physical system.

According to a first aspect of the present embodiments, a computer-implemented method of engineering a physical system may include: providing a set of first engineering artifacts and a set of second engineering artifacts of engineering information of the physical system; determining a first annotation tree including first nodes representing the set of first engineering artifacts and determining a second annotation tree comprising second nodes representing the set of second engineering artifacts; providing at least one ontology relating to the engineering information; determining a respective similarity value of the respective first node and the respective second node using the respective ontology, where the respective similarity value depends on a respective distance between the respective first node and the respective second node in the respective ontology; determining at least one of the first nodes that is related to at least one of the second nodes using the respective similarity value; and generating a respective connector linking the respective first engineering artifact corresponding to the respective first node with the respective second engineering artifact corresponding to the related, respective second node.

According to a second aspect of the present embodiments, a computer system may be arranged and configured to execute the acts of the computer-implemented method according to the first aspect of the present embodiments.

According to a third aspect of the present embodiments, a computer program product may include computer program code that, when executed by the computer system according to the second aspect of the present embodiments, causes the computer system to carry out the method according to the first aspect of the present embodiments.

According to a fourth aspect of the present embodiments, a computer-readable medium may include the computer program product according to the third aspect of the present embodiments. By way of example, the described computer-readable medium may be non-transitory and may further be a software component on a storage device.

### BRIEF DESCRIPTION OF THE DRAWINGS

FIGS. 1-4 illustrate a functional block diagram of an example system that facilitates engineering a physical system, especially improving the traceability of the engineering information of the physical system, in a product system, respectively.

FIGS. 5-6 illustrate an example annotation tree in the context of facilitating engineering a physical system, especially improving the traceability of the engineering information of the physical system, in a product system, respectively.

FIGS. 7-9 illustrate an example ontology in the context of facilitating engineering a physical system, especially improving the traceability of the engineering information of the physical system, in a product system, respectively.

FIGS. 10-11 illustrates a flow diagram of an example methodology that facilitates engineering a physical system, especially improving the traceability of the engineering information of the physical system, in a product system, respectively.

FIG. 12 illustrates a block diagram of a data processing system in which an embodiment may be implemented.

### DETAILED DESCRIPTION

Various technologies that pertain to systems and methods for engineering a physical system in a product system will now be described with reference to the drawings, where like reference numerals represent like elements throughout. Those skilled in the art will understand that the principles of the present disclosure may be implemented in any suitably arranged apparatus. It is to be understood that functionality that is described as being carried out by certain system elements may be performed by multiple elements. Similarly, for example, an element may be configured to perform functionality that is described as being carried out by multiple elements.

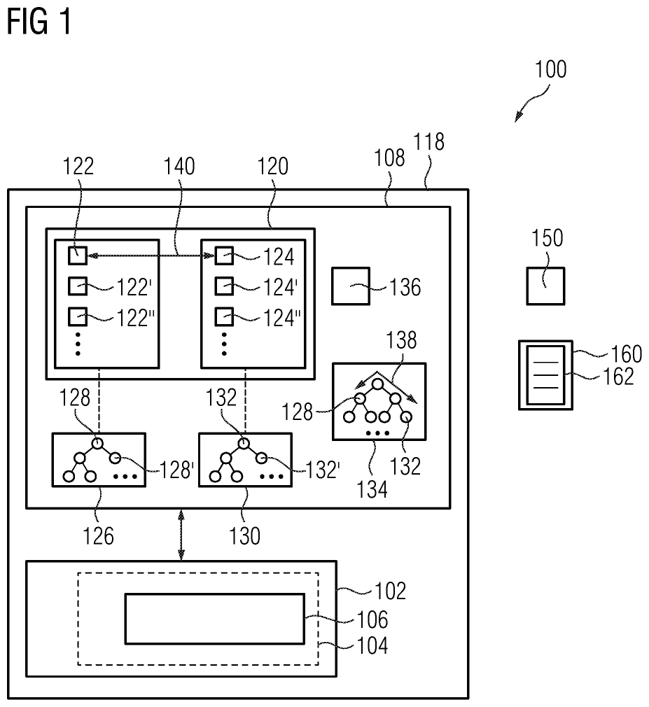

With reference to FIG. 1, a functional block diagram of an example data processing system 100 that facilitates engineering a physical system 150 (e.g., improving the traceability of the engineering information 120 of the physical system 150) is illustrated. The data processing system 100 may, in some examples, include an engineering system 118 or, more generally, a computer system allowing for engineering a physical system 150 by providing corresponding functionalities to a user. The engineering system 118 may include at least one processor 102 that is configured to execute at least one application software component 106 from a memory 104 accessed by the processor 102. The application software component 106 may be configured (e.g., programmed) to cause the processor 102 to carry out various acts and functions described herein. For example, the described application software component 106 may include and/or correspond to one or more components of an engineering software application, such as a CAD, CAM, CAE, or EDA software application or PLM or ALM software application that is configured to generate and store product data in a data store 108 such as a database.

By way of example, the engineering system 118 may allow for the engineering of a physical system 150 by providing corresponding functionalities to a user and by creating, amending, or managing corresponding engineering information relating to the physical system 150. The engineering system 118 may, for example, allow for the management of lifecycle information that may be comprised by the engineering information 120 by providing corresponding functionalities to a user and by creating, amending, or managing corresponding lifecycle information relating to the physical system 150. In such examples, the engineering 118 may include or be part of a product lifecycle management system.

It should be appreciated that in some examples, the physical system 150 may include or be a sensor, an actuator, such as an electric motor, a valve, or a robot, an inverter supplying an electric motor, a gear box, a programmable logic controller (PLC), a communication gateway, and/or other parts or components relating to industrial automation products and industrial automation in general. The physical system 150 may be part of a complex production line or production plant (e.g., a bottle filing machine, conveyor, welding machine, welding robot, etc.). In some examples, the physical system 150 may be a smartphone, smartwatch, handheld, pad, laptop or the like, or a desktop device (e.g., including desktop computers) or other “smart” devices (e.g., smart television sets, fridges, home or industrial automation devices, where smart television sets may be a television set with integrated Internet capabilities or a set-top box for television that offers more advanced computing ability and connectivity than a contemporary basic television set). Further, by way of example, the physical system 150 may include or be any machine or complex E/E product (e.g., cars, aircraft, or structure) or other items, including bridges, tunnels, roads, vehicles, and buildings, that may be engineered.

Examples of engineering systems 118 that may be adapted to include such a device include Simcenter Amesim, an application produced by Siemens Industry Software NV, of Leuven, Belgium, the NX suite of applications, the Solid Edge applications or the Capital suite of applications produced by Siemens Industry Software Inc., of Plano, Texas, USA or the Totally Integrated Automation (TIA) Portal, an application produced by Siemens Aktiengesellschaft, of Munich, Germany. Examples of PLM systems that may be adapted to support the features described herein may include the Active Workspace features of Teamcenter, an application produced by Siemens Industry Software Inc., of Plano, Texas, USA. Examples of ALM systems that may be adapted to support the features described herein may include Polarion ALM, an application produced by Siemens Industry Software GmbH, of Zurich, Switzerland. However, it should be appreciated that the systems and methods described herein may be used in other product systems (e.g., PLM, PDM, ALM systems) and/or any other type of system that generates and stores product data in a database. Also, examples of databases that may be used as one or more data stores described herein include database server applications such as Oracle, Microsoft SQL Server, or any other type of data store that is operative to store data records.

By way of example, the engineering system 118 may be cloud-based, internet-based, and/or be operated by a provider. The user may be located close to the engineering system 118 or remote from the engineering system 118 (e.g., anywhere else; using a mobile device for connecting to the engineering system 118; via the internet). The device of the user may include an input device 110 and a display device 112. In some examples, the engineering system 118 may be installed and run on a device of the user, such as a computer, laptop, pad, on-premises computing facility, or the like.

Traceability of engineering information 120 is an essential element of the software/system development process and hence of the engineering of a physical system 150. Traceability may be required in safety-critical systems by all safety standards and may be mandatory to reach certification. As an example, such a standard may be ISO 26262, titled “Road vehicles-Functional safety,” which is an international standard for functional safety of electrical and/or electronic systems that are installed in serial production road vehicles (e.g., excluding mopeds). Another example of such a standard may be IEC 61508, titled “Functional Safety of Electrical/Electronic/Programmable Electronic Safety-related Systems (E/E/PE, or E/E/PES).” Traceability establishment and maintenance may be time consuming, hard to achieve, and error-prone, especially when many trace links are to be maintained manually. For example, when different stakeholders are involved in the development process, a requirement or a design decision change may require the knowledge of what design artifacts are to be changed accordingly. Traceability links help to identify the required changes immediately without personal communication between stakeholders. For example, to satisfy the functional safety standards ISO 26262 or IEC 61508, it is required to establish traceability links between engineering artifacts with the purpose to show, for example, that all safety requirements are implemented, but often traceability links are absent due to some reasons (e.g., legacy artifacts, migration, software evolution, lack of a disciplined development, and maintenance process, etc.). However, the traceability among the whole development process is required for the later proof that the developed physical system 150 is safe. Otherwise, it is very hard or even impossible to prove that the physical system 150 is safe.

It should further be appreciated that it may be difficult and time-consuming to manage engineering information 120 (e.g., data records representing/storing data corresponding to parts, tools, models, requirements specifications, test information, test cases, test management information, risks, or hazards) in complex, production engineering, PLM, or ALM environments. For example, engineering information 120 may be spread in several if not many engineering documents, where these engineering documents may be large files including comprehensive engineering information.

It should also be appreciated that a reliable and efficient traceability of engineering information 120 may be challenging. In some examples, managing engineering information 120, especially safeguarding a reliable and efficient traceability of engineering information 120, may require many conscious selections and inputs by trained and experienced users or may require large computation or memory resources that may be an error-prone, slow, or not efficient process. According to some approaches, establishment of traceability may be done as follows. A person responsible for establishment of traceability links is not the original author of models and other engineering information. The current trend to offshore and outsource makes the problem bigger, since the person responsible for modelling and requirements may be not reached within the company.

By way of example, the described processing system 118 or 100 may include at least one input device 110 and at least one display device 112 (e.g., a display screen). The described processor 102 may be configured to generate a graphical user interface (GUI) 114 through the display device 112. Such a GUI may include GUI elements such as buttons, links, search boxes, lists, text boxes, images, scroll bars usable by a user to provide inputs through the input device 110 that cause managing engineering information 120.

To enable the enhanced engineering of a physical system 150, especially to improve the traceability of the engineering information 120 of the physical system 150, the application software component 106 and/or the processor 102 may, in some examples, be configured to provide a set of first engineering artifacts 122 and a set of second engineering artifacts 124 of engineering information 120 of the physical system 150.

The engineering information 120 may, for example, include information characterizing the physical system 150 or at least components of the physical system 150 (e.g., with respect to one or more engineering disciplines, such as mechanical, electric or electronic engineering, or with respect to the product lifecycle of the physical system 150). The set of first engineering artifacts 122 and the set of second engineering artifacts 124 that are comprised by the engineering information 120 may, in some examples, be stored in separate engineering documents and/or be engineered in using different engineering tools. For example, the set of first engineering artifacts 122 may relate to mechanical and thermal aspects of the physical system 150 and may be engineered in a mechanical engineering tool, whereas the set of second engineering artifacts 124 may relate to electrical and magnetic aspects of the physical system 150 and may be engineered in an electrical and medical engineering tool. In some examples, the engineering information 120 (e.g., the set of first engineering artifact 122 and/or the set of second engineering artifact 124) may include requirements or test cases that the physical system 150 may need to fulfill, whereby such engineering information 120 may, in some examples, be stored in a separate engineering document and/or be engineered in the separate engineering or lifecycle management tool. Further, in some examples, the above-mentioned different documents are created or edited by different users that may use different engineering tools that may make it challenging to identify and link related engineering information 120 of the physical system 150.

By way of example, the application software component 106 and/or the processor 102 may further be configured to determine a first annotation tree 126 including first nodes 128 representing the set of first engineering artifacts 122 and determining a second annotation tree 130 including second nodes 132 representing the set of second engineering artifacts 124.

The first annotation tree 126 and the second annotation tree 130 may, by way of example, be determined using a parser, such as the Stanford Parser available at https://nlp.stanford.edu/software/lex-parser.shtml. Herein, a parser may, for example, be understood as a tool for analyzing a string of symbols, either in natural language, computer languages, or data structures, conforming to the rules of a formal grammar. A formal analysis of a sentence or other string of words (e.g., the set of first engineering artifacts 122 and a set of second engineering artifacts 124) may be performed into its constituents, resulting in an annotation tree (e.g., first annotation tree 126 and the second annotation tree 130), showing their syntactic relation to each other, which may also contain semantic and other information.

An annotation tree may, in some examples, be referred to as a parse tree or syntax tree that may, for example, be annotated. In the present patent document, the terms parse tree, syntax tree, or annotation tree are understood to be basically equivalent and interchangeable. The respective annotation tree 126, 130 may include respective nodes 128, 132 that may, for example, denote a construct occurring in the analyzed text (e.g., the sets of the respective engineering artifacts 122, 124). Accordingly, the first nodes 128 may represent the set of first engineering artifacts 122, and the second nodes 132 may represent the set of second engineering artifacts 124. The nodes 128, 132 of the respective annotation tree 126, 130 may be connected pairwise to form paired nodes (e.g., vertices), whose elements are referred to as edges (e.g., links or lines).

In some examples, for the determination of the respective annotation tree 126, 130, the respective engineering artifacts 122, 124 may be used as an input (e.g., of the parser), and the respective annotation tree 126, 130 is the output of this determination.

The application software component 106 and/or the processor 102 may, in some examples, further be configured to provide an ontology 134 relating to the engineering information 120.

Herein, an ontology 134 may, for example, be understood to encompass a representation, formal naming, and definition of the categories, properties, and relations between the concepts, data, and entities that substantiate one, many, or all domains of discourse (e.g., the engineering information 120 of the physical system 150). In general terms and more simply, an ontology 134 may, for example, be a way of showing the properties of a subject area (e.g., the engineering information 120 of the physical system 150) and how they are related by defining a set of concepts and categories that represent the subject. In some examples, the ontology 134 may be a graph so that one element of the ontology 134 may be connected with at least one other element of the ontology 134, whereby there may be chains of connected elements.

In some examples, the ontology 134 may be specific to the physical system 150 or the corresponding engineering information 120 that may, in some examples, currently be engineered. In further examples, the ontology may be more generic and may, for example, cover one or more engineering disciplines, such as mechanical, electric, or electronic engineering, and/or aspects of product lifecycle management, such as requirements or test cases that the physical system 150 may need to comply with. By way of example, the ontology 134 may include one or more of the first nodes 128 and/or the second nodes 132.

Examples of such ontologies 134 may, for example, include: AURUM—Information Security Ontology, an ontology for information security knowledge sharing, enabling users to collaboratively understand and extend the domain knowledge body, which may serve as a basis for automated information security risk and compliance management; General Automotive Ontology (GAO)—an ontology for the automotive industry that includes ‘car’ extensions; Computer Science Ontology—an automatically generated ontology of research topics in the field of Computer Science; POPE—the Purdue Ontology for Pharmaceutical Engineering; RXNO Ontology—for name reactions in chemistry; SSN/SOSA—the Semantic Sensor Network Ontology (SSN) and the Sensor, Observation, Sample, and Actuator Ontology (SOSA), which are W3C Recommendation and OGC Standards for describing sensors and their observations; PLM-RDL ontology—based on the ISO 15926-14 ontology describing industrial assets (cf. https://rds.posccaesar.org/home).

Further ontologies may, for example, be found using the DAML Ontology library or the OntoSelect library. In addition, Siemens AG, of Munich, Germany also develops and provides ontologies and ontology libraries for typical industrial environments and use cases.

In some examples, two or more ontologies 134 that may relate to the engineering information 120 may be provided. This may, for example, be the case if the set of first engineering artifacts 122 is related to one engineering or product lifecycle management aspect, and the set of second engineering artifacts 124 is related to another, different engineering or product lifecycle management aspect. If, in some examples, two or more ontologies 134 are used as a basis, a combined ontology 134 may be determined including the underlying ontologies 134 (e.g., by combining the underlying ontologies 134), which may, in some examples, have one or more nodes in common, respectively).

The application software component 106 and/or the processor 102 may, for example, further be configured to determine a respective similarity value 136 of the respective first node 128 and the respective second node 132 using the respective ontology 134. The respective similarity value 136 depends on the respective distance 138 between the respective first node 128 and the respective second node 132 in the respective ontology 134. As already mentioned above, the respective ontology 134 may, in some examples, include one or more of the first nodes 128 and/or the second nodes 132. In some examples, the similarity value 136 of the respective first node 128 and the respective second node 132 may correspond to the distance 138 between the two nodes 128, 132 (e.g., the length of the shortest path linking the two nodes 128, 132 in the respective ontology 134, respectively). The similarity value 136 may, for example, be the inverse of distance 138 or the length of the shortest path between the two mentioned nodes 128, 132 in the respective ontology 134. Hence, distance 138 may, by way of example, be understood as the length of the chain or the number of nodes in the graph of the ontology 134 between the two nodes 128, 132. In some examples, the similarity value 136 may represent a certain probability of a similarity chance.

For example, as illustrated in FIG. 1, the shortest path from the first node 128 to the second node 132 in the illustrated ontology 134 includes the two nodes 128 and 132, as well as the two nodes positioned between the two nodes 128 and 132. Hence, the distance 138 may, for example, be counted four nodes in the example illustrated in FIG. 1. The distance 138 of neighboring, linked nodes 128, 132 may accordingly, in some examples, be counted as two nodes.

In further examples, the similarity value 136 of the respective first node 128 and the respective second node 132 may be 0, if at least one of the two mentioned nodes 128, 132 is not comprised by the ontology 134. Further, the similarity value 136 of the respective first node 128 and the respective second node 132 may be 1 (e.g., if the two mentioned nodes 128, 132 are comprised by the ontology 134 and basically coincide; by being positioned at the same position in the respective ontology 134, which may be represented by a tree or other graph).

Accordingly, the respective similarity value 136 may be determined for a given pair of one of the first nodes 128 and one of the second nodes 132 using the respective ontology 134. The determination of the respective similarity value 136 may, for example, be done for some or all of the mentioned pairs of nodes 128, 132.

In some examples, the application software component 106 and/or the processor 102 may further be configured to determine at least one of the first nodes 128 that is related to at least one of the second nodes 132 using the similarity value 136.

Pairs of one of the first nodes 128 and one of the second nodes 132 may be determined, which may, for example, have or exceed a certain, respective similarity value 136 that may indicate that the respective first node 128 and the respective second node 132 may be related to each other. Hence, the respective similarity value 136 may be used to determine related first nodes 128 and second nodes 132.

The application software component 106 and/or the processor 102 may, by way of example, further be configured to generate a respective connector 140 linking the respective first engineering artifact 122 corresponding to the respective first node 128 with the respective second engineering artifact 124 corresponding to the related, respective second node 132.

The related first nodes 128 and second nodes 132 may then, in some examples, be used to determine the underlying, respective first engineering artifact 122, which may be related to the underlying, respective second engineering artifact 124. Hence, for a determined, related pair of one of the first nodes 128 and one of the second nodes 132, the corresponding pair of the respective first engineering artifact 122 (e.g., corresponding to the related first node 128) and the respective second engineering artifact 124 (e.g., corresponding to the related second node 132) may be determined and linked by generating the respective connector 140 linking the two mentioned, related engineering artifacts 122, 124.

The respective connector 140 may, in some examples, considerably facilitate and help to establish the traceability of the engineering information 120 that may, for example, be required to proof compliance of the engineered physical system 150 with certain requirements or standards, such as the above-mentioned functional safety standards ISO 26262 or IEC 61508.

In some examples, the respective connector 140 linking respective, related engineering artifacts 122, 124 may be generated for some or all of the mentioned pairs of related engineering artifacts 122, 124. Hereby, it should be appreciated that in some examples, such connectors 140 may be generated linking one of the first engineering artifacts 122 with two or more, related second engineering artifacts 124 and/or vice versa.

By way of example, the generated connector 140 may include a Uniform Resource Locator (URL), a Uniform Resource Identifier (URI), and/or a Requirements Interchange Format (ReqIF) element. Herein, the respective connector 140 may make use or consist of a URI, URL, and/or an ReqIF element that links the respective first engineering artifact 122 corresponding to the respective first node 128 with the respective second engineering artifact 124 corresponding to the related, respective second node 132.

In some examples, the respective connector 140 is only generated if the respective first engineering artifact 122 corresponding to the respective first node 128 is not yet linked with the respective second engineering artifact 124 corresponding to the related, respective second node 132. In these examples, there may first be a determination if the two mentioned engineering artifacts 122, 124 are already linked, and only if the two mentioned engineering artifacts 122, 124 are not yet linked, the corresponding respective connector 140 is generated.

It should be appreciated that the respective connector 140 may, for example, be understood as a trace in the context of traceability or as a recommender in the context of information filtering systems.

By way of example, the set of first engineering artifacts 122, the set of second engineering artifacts 124, the engineering information 120, the first annotation tree 126, the second annotation tree 130, the respective ontology 134, the respective similarity value 136, and/or the respective connector 140 may be stored in the data store 108. In some examples, the set of first engineering artifacts 122 may alternatively or additionally be stored in a first engineering database 142. In further examples, the set of second engineering artifacts 124 may alternatively or additionally be stored in the second engineering database 142′.

In some examples, the set of first engineering artifacts 122 and optionally the set of second engineering artifacts 124 includes engineering information relating to physical, mechanical, electrical, electronic, hydraulic, thermal, control, electric power, and/or process-oriented information or model of the physical system 150. Optionally, the set of second engineering artifacts 124 includes lifecycle information relating to the conception, requirements, test cases, risks, hazards, uses cases, issues, design, realization, and/or service information of the physical system 150.

In further embodiments, the requirements, test cases, risks, or hazards comprised by the lifecycle information may further include requirements specifications, test information, test management information, or risk assessments with respect to the physical system 150. The lifecycle information, especially the test information, test cases, test management information, risks, hazards, or risk assessments, may be used to qualify the physical system 150 as compliant with certain requirements or specifications or to find issues of the physical system 150. By way of example, the lifecycle information or more generally the engineering information 120 may be used to assess whether the engineered physical system 150 compliance with certain standards (e.g., the above-mentioned functional safety standards ISO 26262 or IEC 61508).

It should be appreciated that, by way of example, the application software component 106 and/or the processor 102 may further be configured to: determine if the respective first engineering artifact 122 is consistent with the connected, respective second engineering artifact 124; display the respective result 146 of the determination of the consistency of the respective first engineering artifact 122 with the connected, respective second engineering artifact 124 to a user via an engineering user interface (UI) 116; and/or store the respective result 146 of the determination of the consistency of the respective first engineering artifact 122 with the connected, respective second engineering artifact 124 in an engineering database 142.

For example, the respective first engineering artifact 122 may be determined to be consistent with the connected, respective second engineering artifact 124 if the two mentioned engineering artifacts 122, 124 concur with each other or at least do not contradict each other. For example, if the first engineering artifact 122 states that the length of a component of the physical system 150 is in the range of 2.5 mm to 3 mm and the second engineering artifact 124 states that the length of the same component of the physical system 150 has a length of 2.8 mm, then the two mentioned engineering artifacts 122, 124 may be determined to be consistent with each other. If, however, the second engineering artifact 124 states that the length of the same component of the physical system 150 is 3.1 mm, then the two mentioned engineering artifacts 122, 124 may be determined to be inconsistent with each other. The explained determination may provide the respective result 146, which may be that the two mentioned engineering artifacts 122, 124 may either be consistent or not be consistent with each other.

The respective result 146 of the explained determination may then, in some examples, be displayed to a user via the engineering UI 116. The respective result 146 may, in some examples, be displayed to the user only if the two mentioned engineering artifacts 122, 124 are determined not to be consistent with each other. Then, the user may get aware of the found inconsistency and may investigate and optionally amend at least one of the two mentioned engineering artifacts 122, 124 and/or the generated connector 140 (e.g., if the two mentioned engineering artifacts 122, 124 should not be linked to each other).

Alternatively or additionally to the display of the respective result 146, the respective result 146 may be stored in the engineering database 142. Storing the respective result 146 in the engineering database 142 may facilitate verifying the found relations between the mentioned engineering artifacts 122, 124 and may hence facilitate validating or retracing the real traceability of the engineering information 120.

In some examples, the engineering database 142 may be stored in the data store 108.

In further examples, the determination of the consistency of the respective first engineering artifact 122 with the connected, respective second engineering artifact 124 may further include: if the respective first engineering artifact 122 and the connected, respective second engineering artifact 124 include engineering information 120 relating to a respective physical, mechanical, electrical, electronic, hydraulic, thermal, control, electric power, and/or process-oriented model of the physical system 150, determining if the respective model of the respective first engineering artifact 122 is consistent with the respective model of the connected, respective second engineering artifact 124; or if the respective first engineering artifact 122 includes engineering information 120 relating to a respective physical, mechanical, electrical, electronic, hydraulic, thermal, control, electric power, and/or process-oriented model of the physical system 150 and the connected, respective second engineering artifact 124 includes lifecycle information relating to the requirements, test cases, risks, hazards, and/or uses cases of the physical system 150, determining if the model of the respective first engineering artifact 122 is consistent with the requirements, test cases, risks, hazards, and/or uses cases of the connected, respective second engineering artifact 124.

If both the respective first engineering artifact 122 and the connected, respective second engineering artifact 124 include the respective model of the physical system 150, the two models may be compared to determine whether the two models and hence the two mentioned engineering artifacts 122, 124 are consistent with each other. In some examples, the respective model may include a CAD, CAM or electronic/EDA model of the physical system 150 or at least a part of the physical system 150. For the example of a respective CAD model, the geometric dimensions, the geometric dimensioning and tolerancing (GD&T), the surface quality, etc. of the model of the respective first engineering artifact 122 and of the model of the respective second engineering artifact 124 may be compared to determine whether the two models are consistent with each other. In further examples, an electronic model comprised by the respective first engineering artifact 122 and a CAD model comprised by the respective second engineering artifact 124 may be compared. The connections, positions, lengths, and/or sections of electric conductors or circuits may be comprised by both models.

If the respective first engineering artifact 122 includes the respective model of the physical system 150 and the connected, respective second engineering artifact 124 includes lifecycle information relating to the requirements, test cases, risks, hazards, and/or uses cases of the physical system 150, the models may be compared with the mentioned lifecycle information to determine whether the model and hence the respective first engineering artifact 122 is consistent with the mentioned lifecycle information and hence the respective second engineering information 124. In some examples, the lifecycle information may include requirements (e.g., relating to safety requirements of the functional safety standards ISO 26262 or IEC 61508, such as the deactivation of a certain feature, such as opening the doors of a vehicle, if a certain condition is fulfilled, such as a vehicle speed exceeding 15 km/h). The model comprised by the respective first engineering artifact 122 may, for example, include control information defining features and the availability or function. Then, the features comprised by the model may be compared with the requirements of the lifecycle information to determine whether the model is consistent with the requirements. Further, the model may include control information to avoid an unwanted execution of the feature if a certain condition is not fulfilled, where the control information may deactivate the mentioned feature according to a first approach, and, in some examples, additionally, a redundant second approach may be comprised by the control information to safeguard that the feature is not executed unintentionally if the first approach fails for some reason. This sort of redundant control information comprised by the model may, in some examples, also be compared with corresponding requirements that may require redundant approaches for safety-relevant features. Such redundant approaches may, for example, be applied in the context of ASIL decomposition, whereby ASIL stands for Automotive Safety Integrity Level and ASIL-oriented and safety-oriented analysis is comprised as part 9 by the functional safety standard ISO 26262.

In some examples, the lifecycle information may include risks or hazards (e.g., in the context of the four ASIL levels that range from ASIL-A (low risk reduction needed) to ASIL-D (high risk reduction needed) assuming that the physical system 150 is a vehicle or part of a vehicle). Three factors may determine the ASIL requirement for a particular physical system 150. The first is severity (e.g., if the physical system 150 were to fail, how bad could the safety consequences potentially be on the driver, passengers, or nearby pedestrians and vehicles?). The second is probability of exposure (e.g., the likelihood of an operational situation that may be hazardous if coincident with the failure mode under analysis). And the third is controllability (e.g., if the physical system 150 were to fail, what is the ability to avoid a harm through the timely reactions of the persons involved in the operational situation (driver, passengers, or persons in the vicinity of the vehicle)).

For example, say the driver's brakes fail during a high-speed operational situation in crowded streets, this would have a serious effect on the driver's ability to control the vehicle. There is a chance the driver or others may get badly hurt as a result. This risk would be classified as ASIL-D in this case. A way to engineer a physical system 150 that complies with ASIL-D requirements may, for example, be to develop a fail-operational design that incorporates resilience at three layers: compute, network, and power. If a compute node fails, redundant compute resources may bring the vehicle to a safe stop. The network uses an innovative dual-ring topology for full redundancy in the data network, and a dual-ring topology for power, coupled with smart fusing, provides that zone controllers may deliver affordable, fail-operational performance. Hence, the hazard (e.g., of a brake failure) and the involved risk may be defined (e.g., involving the severity, probability, and controllability of the occurrence of the hazard, such as potential harm done to the driver or others, how often this may occur, and how easy it is to avoid this). Further, besides the hazard and the risk, the measures (e.g., requirements, test cases, test scenarios, or use cases) to adequately cope with the hazard and the risk may be comprised by the lifecycle information, which may then be compared with the model to assess whether the respective first engineering artifact 122 is consistent with the respective second engineering artifact 124. In some examples, only the measures (e.g., requirements, test cases, test scenarios, or use cases) to adequately cope with the hazard and the risk may be comprised by the lifecycle information.

It should be appreciated, that in some examples, the application software component 106 and/or the processor 102 may further be configured to, if the respective connector 140 has been generated and optionally if the respective first engineering artifact 122 is consistent with the connected, respective second engineering artifact 124, produce the physical system 150 according to the engineering information 120.

In some examples, the physical system 150 may only be produced according to the engineering information 120 if the respective connector 140 (e.g., for all identified, related engineering artifacts 122, 124) has been generated. Optionally, the physical system 150 may only be produced according to the engineering information 120 if the respective first engineering artifact 122 is consistent with the connected, respective second engineering artifact 124. The determination of the mentioned consistency is explained above. For example, the above-explained, respective result 126 may reflect the outcome of the mentioned determination of the consistency of the respective the respective first engineering artifact 122 and the connected, respective second engineering artifact 124. If, for example, the respective models of two connected engineering artifacts 122, 124 are determined (not) to be consistent with each other, then the physical system 150 may (not) be produced. Further, if the model of the respective first engineering artifact 122 is determined (not) to be consistent with measures (e.g., requirements, test cases, test scenarios, or use cases) to adequately cope with the hazard and the risk that have been identified for the physical system, then the physical system 150 may (not) be produced.

By way of example, the application software component 106 and/or the processor 102 may further be configured to, if the respective connector 140 has been generated and optionally if the respective first engineering artifact 122 is consistent with the connected, respective second engineering artifact 124, engineer, model, simulate, analyze, operate, and/or control the physical system 150 using the engineering information 120.

In some embodiments, the application software component 106 and/or the processor 102 may further be configured to: display the respective first engineering artifact 122 corresponding to the respective first node 128 and the respective second engineering artifact 124 corresponding to the related, respective, second node 132 to the user via the engineering UI 116; capture an input by the user relating to an approval or a dismissal of generating the respective connector 140 in response to user interactions with the engineering UI 116; and generate the respective connector 140 only upon the approval by the user of generating the respective connector 140.

According to these embodiments, the user is provided with additional control with respect to the generation of the respective connector 140 (e.g., since the generation of the respective connector may provisionally only be recommended to the user). First, a pair of related nodes 128, 132 may be determined using the respective similarity value 136. The pair related engineering artifacts 122, 124 that correspond to the determined pair of related nodes 128, 132 may then be displayed to the user via the engineering UI 116. Optionally, the generation of a respective connector 140 linking the tool, related engineering artifact 122, 124 may be suggested to the user via the engineering UI 116. The user may then provide his or her input indicating the approval or dismissal of the generation of the respective connector 140, whereby the respective connector 140 may only be generated if the user has provided his or the approval.

In some examples, if the user rejects the suggested generation of the respective connector 140, the respective connector 140 may not be generated, and the respective first engineering artifact 122 and the related, respective second engineering artifact 124 may not be linked. For example, if the respective first engineering artifact 122 and the related, respective second engineering artifact 124 already have been made previously, this previous link may be deleted if the user rejects the suggested generation of the respective connector 140. This approach may, in some examples, provide the possibility to the user to get aware of an inconsistency and to investigate and optionally amend at least one of the two mentioned engineering artifacts 122, 124.

It should be appreciated that, in some embodiments, it may be highly recommended from the customer that each suggested connector 140 is still reviewed by a user (e.g., an engineer) because of safety reasons. Hence, the respective connector 140 (e.g., a trace link) may only be generated under approval of a user or an engineer. Hereby, the advantage of the proposed method may, for example, be a help to navigate through the complexity of engineering information 120, but not to replace a human.

In further examples, the application software component 106 and/or the processor 102 may further be configured to: display a list of at least one of the first engineering artifacts 122 corresponding to at least one of the first nodes 128 and some of the second engineering artifacts 124 corresponding to the related, respective second nodes 132 to the user via the engineering UI 116, where the list is ordered with respect to the respective similarity values 136; capture the input by the user relating to a selection from the listed first engineering artifacts 122 and second engineering artifacts 124 and to an approval or a dismissal of generating the respective connector 140 in response to user interactions with the engineering UI 116; and generate the respective connector 140 only upon the approval by the user of generating the respective connector 140.

The list may, by way of example, include two or more pairs of at least one of the first engineering artifacts 122 and the related second engineering artifacts 124, whereby the mentioned pairs may be ordered with respect to the corresponding, respective similarity value 136. Hereby, the list may include the pairs of engineering artifacts 122, 124 with the highest corresponding similarity values 136, whereby the list may start with the pair of engineering artifacts 122, 124 with the highest similarity value 136 and then list pairs of engineering artifacts 122, 124 according to decreasing similarity values 136.

In some examples, the list may include a number of (e.g., several) pairs of one of the first engineering artifacts 122 and a number (e.g., several) of the related, second engineering artifacts 124. In further examples, the list may include a number of (e.g., several) pairs of a number (e.g., several) of the first engineering artifacts 122 and a number (e.g., several) of the related, second engineering artifacts 124.

In response to the list displayed to the user via the engineering UI 116, the user may select one or more of the listed pairs of engineering artifacts 122, 124 and may approve or dismiss generating the corresponding, respective connector 140 by providing according input. The respective connector 140 may only be generated if the user has provided his or the approval.

The described display of a list of pairs of engineering artifacts 122, 124 may facilitate and accelerate generating the respective connector 140 while providing control and a good overview to the user.

It should be appreciated that, in some examples, the application software component 106 and/or the processor 102 may further be configured to determine the respective first node 128 to be related to the respective second node 132 if the respective similarity value 136 exceeds a given similarity value threshold.

In some examples, the given similarity value threshold may be an absolute value, such as 0.001, 0.01, 0.1, or one third, or may depend on the size of the respective ontology 134. For example, if the respective ontology 134 has (at least in part) the structure of a tree, and a height of the tree may be understood as the total number of nodes in the tree on the path from the root node to the deepest node in the tree, then, in some examples, the given similarity value threshold may be the inverse of (e.g., one fourth or half of) the height of the tree-part of the respective ontology 134. In some examples, the size of the respective ontology 134 may be the number of its edges (e.g., paired vertices or nodes 128, 132, cf. above), whereby the given similarity value threshold may, for example, be the inverse of 0.001, 0.01, 0.1 the size of the respective ontology 134. In further examples, the given similarity value threshold may be determined based on user input identifying the respective first engineering artifact 122 and the respective second engineering artifact 124 as related, whereby the respective similarity value 136 of the corresponding first node 128 and the corresponding second node 132 may be determined and used to determine the given similarity value threshold.

By way of example, the application software component 106 and/or the processor 102 may further be configured to: determine a respective weight 144 of the respective node 128, 132, where the respective weight 144 is representative of the occurrence of the respective engineering artifact 122, 124 corresponding to the respective node 128, 132 in the engineering information 120; and determine at least one of the first nodes 128 that is related to at least one of the second nodes 132 using the similarity value 136 and further using the respective weight 144 of the respective node 128, 132.

For example, the weight 144 of a given first node 128 (w(t)) may be the ratio of the number of times (N(t)) the given first node 128 occurs in the set of the first engineering artifacts 122 and the number of times (QF(t)) the given first node 128 occurs in the set of the first engineering artifacts 122 and in the set of the second engineering artifacts 124 (e.g., hence, w(t)=N(t)/QF(t)). The same applies mutatis mutandis to the weight 144 of a given second node 132. In this way, respective nodes 128, 132 and the corresponding respective engineering artifacts 122, 124 may, for example, be considered for the determination of related nodes 128, 132 according to the number of their occurrence in the respective set of engineering artifacts 122, 124, or generally in the engineering information 120. In some examples, the above-described, respective similarity value 136 may be multiplied with the weights of the two involved nodes 128, 132 to obtain a weighted, respective similarity value 136. Accordingly, a higher or lower weighted, respective similarity value 136 may be assigned to respective nodes 128, 132 and the corresponding respective engineering artifacts 122, 124 that occur more or less often in the respective set of engineering artifacts 122, 124, or generally in the engineering information 120, whereby the weighted, respective similarity value 136 may then be used to determine at least one of the first nodes 128 that is related to at least one of the second nodes 132.

Hereby, the use of the respective weight 144 may, in some examples, improve the determination of related nodes 128, 132.

In some embodiments, the respective node 128, 132 may correspond to a term or a phrase of at least two terms.

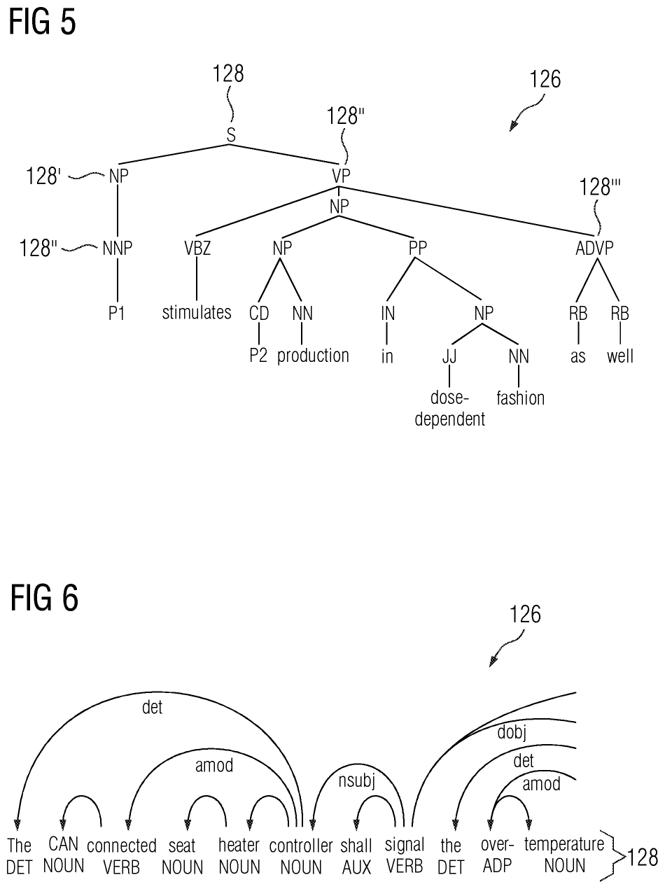

Hereby, the term may, for example, correspond to a single word (e.g., a verb, a noun, a preposition, etc.), or in some examples, a compound noun including at least two of nouns, adjectives, adverbs, verbs, prepositions (e.g., “seat heater controller” (three nouns), “over-temperature” (adverb and noun), “cooling fan” (verb and noun)). The phrase may, for example, include two or more of such terms and, in some examples, correspond to a sentence or a clause (e.g., the sentence illustrated in FIG. 6).

Herein, the above-explained weight 144 may be determined for the respective node 128, 132 corresponding to a term (e.g., a single word or a compound noun) or corresponding to a phrase (e.g., the sentence illustrated in FIG. 6).

In further examples, a term-to-phrase-similarity value of the respective first node 128 including one first term and the respective second node 132 including one second phrase may be the maximum among the individual similarity values 136 of the respective first term and the second terms, where a phrase-to-phrase-similarity value of the respective first node 128 including a first phrase and the respective second node 132 including the second phrase may be the average of the term-to-phrase-similarity value weighted with the respective weight 144 of the respective first term and multiplied with the maximum among the individual weights 144 of the respective first terms.

Hence, the term-to-phrase-similarity value (e.g., sim(t, P<t1, t2, . . . , tn>)) of the respective first node 128 including one first term (e.g., t) and the respective second node 132 including one second phrase (e.g., P<t1, t2, . . . , tn>) may be the maximum (e.g., max (sim(t,ti))) among the individual similarity values 136 (e.g., sim(t,ti)) of the respective first term and the second terms (e.g., sim(t, P<t1, t2, . . . , tn>)=max (sim(t,ti))). In other words, the term-to-phrase-similarity value may be equal to the largest similarity value 136 among the pairs of the first term and the terms comprised by the second phrase.

Further, the phrase-to-phrase-similarity value (e.g., sim(P1,P2)) of the respective first node 128 including a first phrase (e.g., P1) and the respective second node 132 including the second phrase (e.g., P2) may be the average of the term-to-phrase-similarity value (e.g., cf. above: sim(t,P2)) weighted with the respective weight 144 (e.g., w(ti)) of the respective first term (e.g., t) and multiplied with the maximum among the individual weights 144 (e.g., w(ti)) of the respective first terms (e.g., sim(P1,P2)=Σ(w(ti)×sim(ti,P2))/Σw(ti)×max(w(ti))).

It should be appreciated that, in some examples, the term-to-phrase-similarity value and the phrase-to-phrase-similarity value may provide a refined determination of the respective similarity value 136 that may particularly be applicable and useful for more complex, respective nodes 128, 132 that may allow for reflecting and exploiting a particularly comprehensive semantics comprised in the engineering information 120.

By way of example, the suggested method facilitates to manage safety processes by helping to provide requirements coverage and thorough testing, for example, during the development process, but also during the operation of a physical system 150. The suggested method may, for example, contribute to avoid unnecessary costs and even serious hazards that may occur (e.g., during the operation of a physical system 150) due to missed requirements and insufficient verification and validation.

The described application software component 106 and/or the processor 102 may carry out an analogous method of facilitating engineering a physical system 150, especially improving the traceability of the engineering information of the physical system 150.

Further, a computer-readable medium 160 that may include a computer program product 162 is shown in FIG. 1. The computer program product 162 may be encoded with executable instructions that, when executed, cause the computer system 100 or and/or the engineering system 118 to carry out the described method.

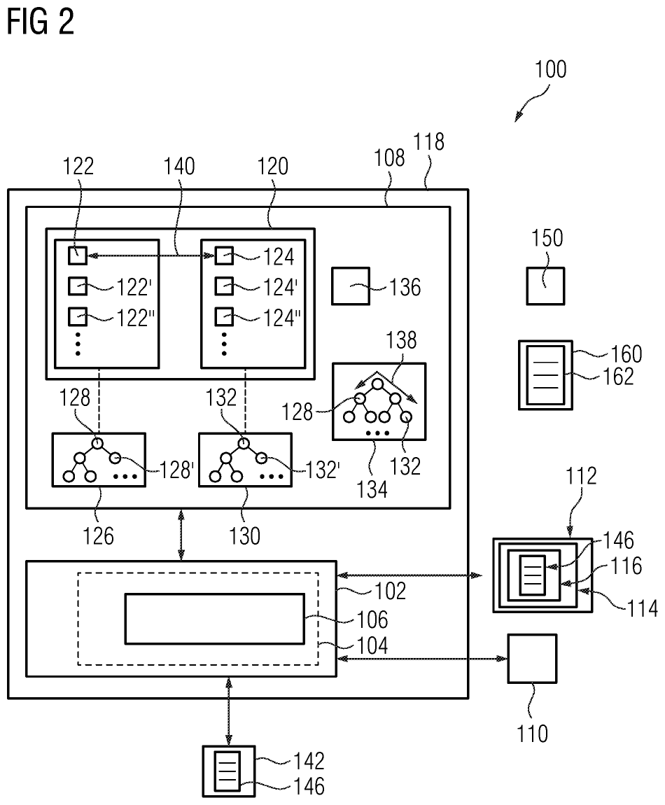

With reference to FIG. 2, a functional block diagram of another example data processing system 100 is illustrated that facilitates engineering a physical system 150, especially improving the traceability of the engineering information 120 of the physical system 150.

Since the data processing system 100 illustrated in FIG. 2 has some similarities with the data processing system 100 illustrated in FIG. 1, some differences are explained in the following. The data processing system 100 illustrated in FIG. 2 includes an engineering UI 116 that may be displayed via the GUI 114 displayed through the display device 112. The engineering UI 116 may display the results 146 of the determination of the consistency of the respective first engineering artifact 122 without connected, respective second engineering artifact 124. Further, the data processing system 100 illustrated in FIG. 2 includes an engineering database 142 in which the result 146 may be stored. Optionally, the set of first engineering artifacts 122, the set of second engineering artifacts 124, the engineering information 120, the first annotation tree 126, the second annotation tree 130, the respective ontology 134, the respective similarity value 136, and/or the respective connector 140 may be stored in the engineering database 142. The data processing system 100 illustrated in FIG. 2 includes an input device 110 to allow the user to provide his or her input.

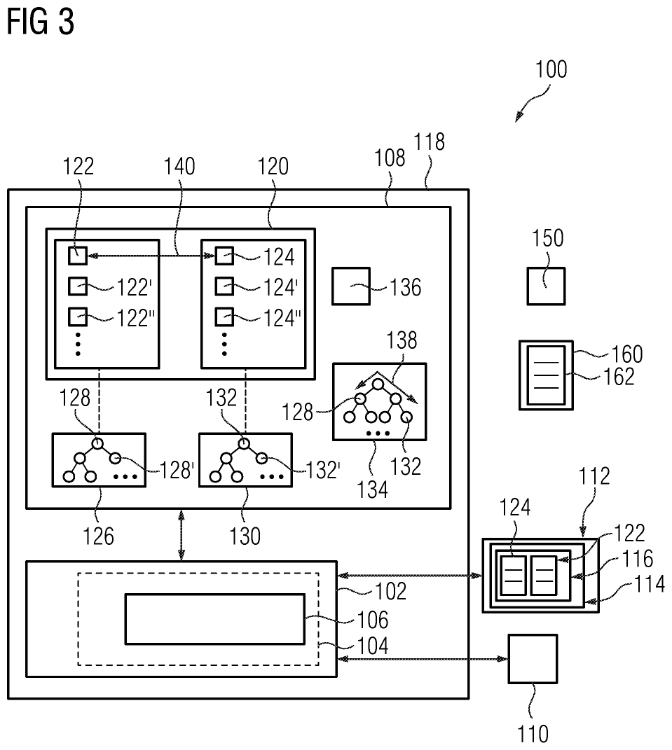

With reference to FIG. 3, a functional block diagram of a further example data processing system 100 is illustrated that facilitates engineering a physical system 150, especially improving the traceability of the engineering information 120 of the physical system 150.

In the engineering UI 116 of the data processing system 100 according to FIG. 3, the respective first engineering artifact 122 corresponding to the respective first node 128 and the respective second engineering artifact 124 corresponding to the related, respective second node 132 may be displayed to the user. The user may then provide his or her input relating to an approval or a dismissal of generating the respective connector 140, where the respective connector 140 may only be generated upon the approval by the user of generating the respective connector 140.

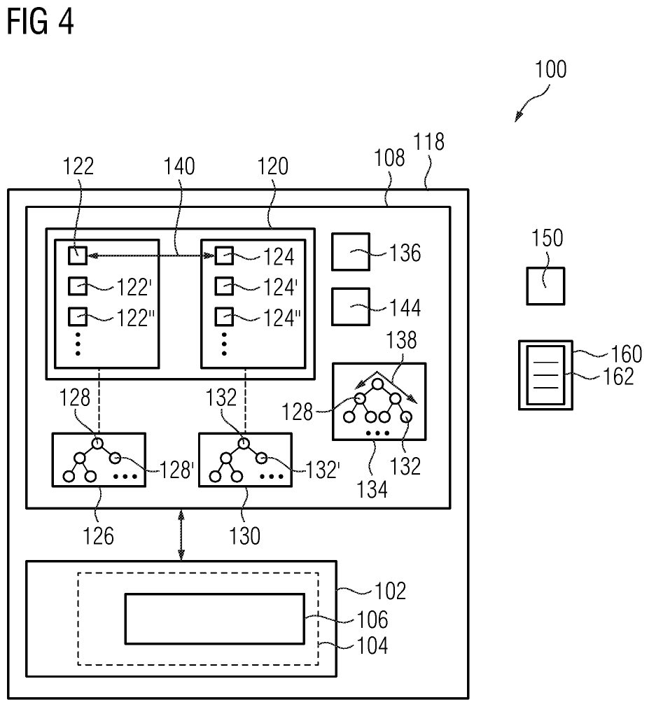

With reference to FIG. 4, a functional block diagram of yet another example data processing system 100 is illustrated that facilitates engineering a physical system 150, especially improving the traceability of the engineering information 120 of the physical system 150.

According to the data processing system 100 according to FIG. 4, the respective weight 144 of the respective note 128, 132 may be determined, where the respective weight 144 is representative of the occurrence of the respective engineering artifact 122, 124 corresponding to the respective note 128, 132 in the engineering information 120. The respective pair of one of the first notes 128 and one of the second notes 132 may then be determined using the similarity value 136 and further using the respective weight 144 of the respective note 128, 132. The respective weight may be stored in the data store 108 or optionally in the engineering database 142.

With reference to FIG. 5, an example annotation tree 126 in the context of facilitating engineering a physical system 150 is illustrated, especially improving the traceability of the engineering information 120 of the physical system 150. The illustrated annotation tree 126 includes a number of (e.g., several) notes 128, 128′, 128″, etc. that are arranged in a tree-like structure and are linked to each other pairwise via edges (e.g., sometimes referred to as links or lines), where the respective node 128 128′, 128″, etc. may be linked via a respective edge with one or more other nodes 128, 128′, 128″, etc.

With reference to FIG. 6, another example annotation tree 126 in the context of facilitating engineering a physical system 150 is illustrated, especially improving the traceability of the engineering information 120 of the physical system 150. The illustrated annotation tree 126 includes words forming a complete sentence, whereby, for example, each word may correspond to a term and hence to a node 128. In some examples, the complete sentence may be identified as a phrase and hence as a node 128.

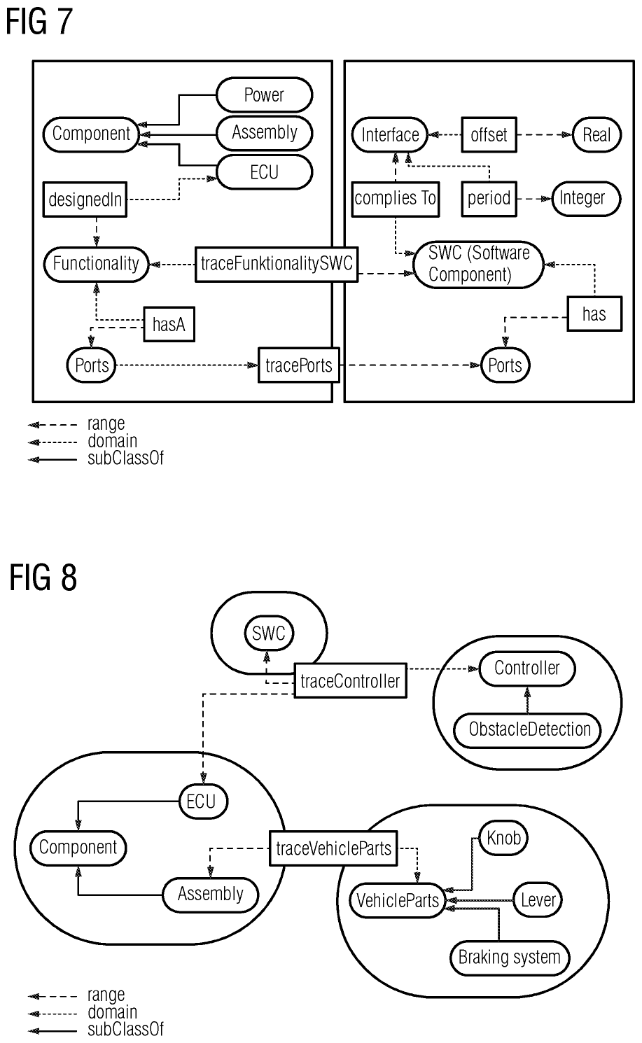

With reference to FIG. 7, an example ontology 128 in the context of facilitating engineering a physical system 150 is illustrated, especially improving the traceability of the engineering information 120 of the physical system 150.

The illustrated ontology 128 includes a number of (e.g., several) nodes 128, such as “Component”, “Functionality”, “Power”, “Interface”, “Ports.” The nodes 128 also include “designedIn,” “hasA,” “offset,” “compliesTo” and further include “traceFunctionalitySWC” and “tracePorts,” whereby the two latter may indicate that the illustrated ontology 128 has been obtained by merging two original, underlying ontologies 128 (illustrated in the left and right box). The illustrated ontology 128 is structured using the relational information “range,” “domain,” and “subClassOf.”

With reference to FIG. 8, another example ontology 128 in the context of facilitating engineering a physical system 150 is illustrated, especially improving the traceability of the engineering information 120 of the physical system 150.

The illustrated ontology 128 includes a number of (e.g., several) nodes 128, such as “Component,” “ECU,” “SWC,” “Controller,” “Know.” The nodes 128 also include “traceController” and “traceVehicleParts,” whereby the two latter may indicate that the illustrated ontology 128 has been obtained by merging at least two original, underlying ontologies 128 (illustrated in the four circles). The illustrated ontology 128 is structured using the relational information “range,” “domain,” and “subClassOf.”

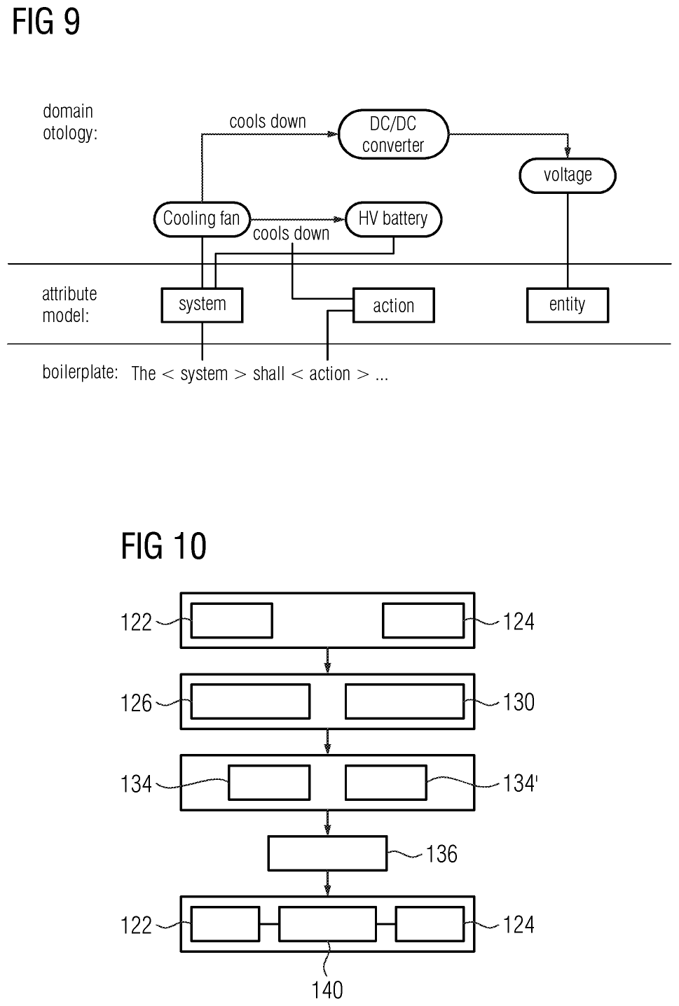

With reference to FIG. 9, a further example ontology 128 in the context of facilitating engineering a physical system 150 is illustrated, especially improving the traceability of the engineering information 120 of the physical system 150.

The illustrated ontology 128 includes a number of (e.g., several) nodes 128 including “Cooling fan,” “DC/DC converter,” and “HV battery,” which are assigned to a “system” aspect of a model of the engineering information 120. The model further includes actions such as “cools down” and “converts,” and entities such as “voltage.” The illustrated ontology 128 may, in some examples, be characterized by the model, whereby a boilerplate, such as “The <system> shall <action> . . . ” may be the origin of the ontology 134 and the comprise model, whereby sentences according to the boilerplate may be provided as respective first engineering artifacts 122, as respective second engineering artifacts 124, or more generally as engineering information 120. In some examples, sentences according to the boilerplate may be provided in the form of a model of the physical system 150 and/or in the form of lifecycle information relating to the requirements, test cases, risks, hazards, uses cases, of the physical system 150, especially in the context of the functional safety standards ISO 26262 or IEC 61508.

Referring now to FIG. 10, a flow diagram of an example methodology is illustrated that facilitates engineering a physical system 150, especially improving the traceability of the engineering information 120 of the physical system 150.

First, a set of first engineering artifacts 122 and a set of second engineering artifacts 124 of engineering information 120 of the physical system 150 may be provided; then, a first annotation tree 126 including first nodes 128 representing the set of first engineering artifacts 122 and a second annotation tree 130 including second nodes 132 representing the set of second engineering artifacts 124 may be determined; then, an ontology 134 and an ontology 134′ (e.g., corresponding to the respective set of engineering artifacts 122, 124) may be provided, whereby a combined ontology 134 relating to the engineering information 120, determined, for example, by merging the underlying ontologies 134, 134′, may be obtained. Then, a respective similarity value 136 of the respective first node 128 and the respective second node 132 using the respective ontology 134 may be determined, where the respective similarity value 136 depends on the respective distance 138 between the respective first node 128 and the respective second node 132 in the respective ontology 134. At least one of the first nodes 128 that is related to at least one of the second nodes 132 may be determined using the respective similarity value 136. A respective connector 140 may be generated linking the respective first engineering artifact 122 corresponding to the respective first node 28) with the respective second engineering artifact 124 corresponding to the related, respective second node 132.

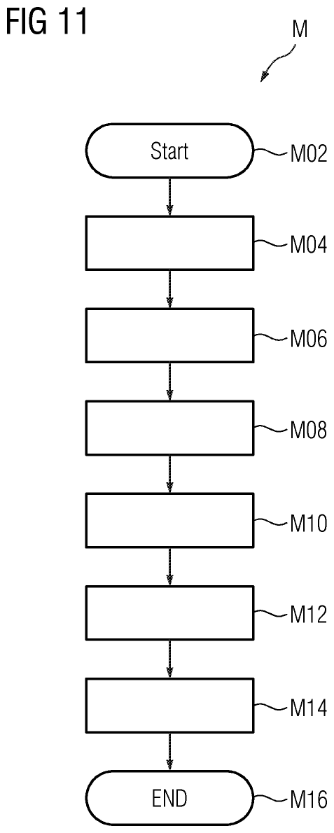

Referring now to FIG. 11, a flow diagram of another example methodology is illustrated that facilitates engineering a physical system, especially improving the traceability of the engineering information of the physical system. The methodology M may start at M02 and may include a number of (e.g., several) acts carried out through operation of at least one processor.

These acts may include: an act M04 of providing a set of first engineering artifacts and a set of second engineering artifacts of engineering information of the physical system; an act M06 of determining a first annotation tree including first nodes representing the set of first engineering artifacts and determining a second annotation tree comprising second nodes representing the set of second engineering artifacts; an act M08 of providing at least one ontology relating to the engineering information; an act M10 of determining a respective similarity value of the respective first node and the respective second node using the respective ontology, where the respective similarity value depends on the respective distance between the respective first node and the respective second node in the respective ontology; an act M12 of determining at least one of the first nodes that is related to at least one of the second nodes using the respective similarity value; and an act M14 of generating a respective connector linking the respective first engineering artifact corresponding to the respective first node with the respective second engineering artifact corresponding to the related, respective second node. At M16, the methodology may end.

The methodology M may include other acts and features discussed previously with respect to the computer-implemented method of engineering a physical system, especially of improving the traceability of the engineering information of the physical system.

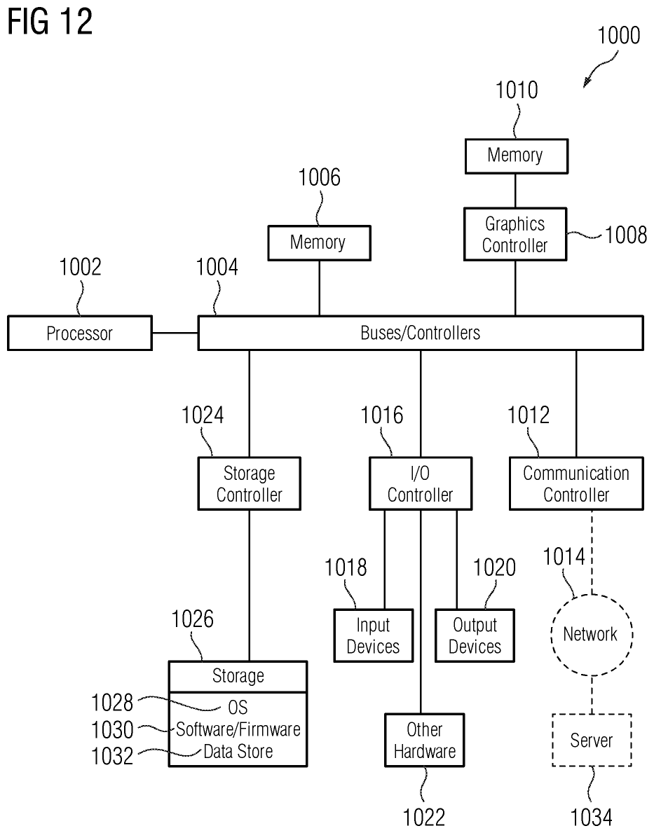

FIG. 12 illustrates a block diagram of a data processing system 1000 (also referred to as a computer system) in which an embodiment may be implemented, for example, as a portion of a product system, and/or other system operatively configured by software or otherwise to perform the processes as described herein. The data processing system 1000 may include, for example, the computer or IT system or data processing system 100 mentioned above. The data processing system depicted includes at least one processor 1002 (e.g., a CPU) that may be connected to one or more bridges/controllers/buses 1004 (e.g., a north bridge, a south bridge). One of the buses 1004, for example, may include one or more I/O buses such as a PCI Express bus. Also connected to various buses in the depicted example may include a main memory 1006 (RAM) and a graphics controller 1008. The graphics controller 1008 may be connected to one or more display devices 1010. In some embodiments, one or more controllers (e.g., graphics, south bridge) may be integrated with the CPU (e.g., on the same chip or die). Examples of CPU architectures include IA-32, x86-64, and ARM processor architectures.

Other peripherals connected to one or more buses may include communication

controllers 1012 (e.g., Ethernet controllers, WiFi controllers, cellular controllers) operative to connect to a local area network (LAN), Wide Area Network (WAN), a cellular network, and/or other wired or wireless networks 1014 or communication equipment.

Further components connected to various busses may include one or more I/O controllers 1016 such as USB controllers, Bluetooth controllers, and/or dedicated audio controllers (e.g., connected to speakers and/or microphones). Various peripherals may be connected to the I/O controller(s) (e.g., via various ports and connections) including input devices 1018 (e.g., keyboard, mouse, pointer, touch screen, touch pad, drawing tablet, trackball, buttons, keypad, game controller, gamepad, camera, microphone, scanners, motion sensing devices that capture motion gestures), output devices 1020 (e.g., printers, speakers), or any other type of device that is operative to provide inputs to or receive outputs from the data processing system. Many devices referred to as input devices or output devices may both provide inputs and receive outputs of communications with the data processing system. For example, the processor 1002 may be integrated into a housing (e.g., a tablet) that includes a touch screen that serves as both an input and display device. Further, some input devices (e.g., a laptop) may include a plurality of different types of input devices (e.g., touch screen, touch pad, keyboard). Also, other peripheral hardware 1022 connected to the I/O controllers 1016 may include any type of device, machine, or component that is configured to communicate with a data processing system.

Additional components connected to various busses may include one or more storage controllers 1024 (e.g., SATA). A storage controller may be connected to a storage device 1026 such as one or more storage drives and/or any associated removable media, which may be any suitable non-transitory machine usable or machine-readable storage medium. Examples include nonvolatile devices, volatile devices, read only devices, writable devices, ROMs, EPROMs, magnetic tape storage, floppy disk drives, hard disk drives, solid-state drives (SSDs), flash memory, optical disk drives (CDs, DVDs, Blu-ray), and other known optical, electrical, or magnetic storage devices drives and/or computer media. Also, in some examples, a storage device such as an SSD may be connected directly to an I/O bus 1004 such as a PCI Express bus.

A data processing system in accordance with an embodiment of the present disclosure may include an operating system 1028, software/firmware 1030, and data stores 1032 (e.g., that may be stored on a storage device 1026 and/or the memory 1006). Such an operating system may employ a command line interface (CLI) shell and/or a graphical user interface (GUI) shell. The GUI shell permits multiple display windows to be presented in the graphical user interface simultaneously, with each display window providing an interface to a different application or to a different instance of the same application. A cursor or pointer in the graphical user interface may be manipulated by a user through a pointing device such as a mouse or touch screen. The position of the cursor/pointer may be changed, and/or an event, such as clicking a mouse button or touching a touch screen, may be generated to actuate a desired response. Examples of operating systems that may be used in a data processing system may include Microsoft Windows, Linux, UNIX, iOS, and Android operating systems. Also, examples of data stores include data files, data tables, relational database (e.g., Oracle, Microsoft SQL Server), database servers, or any other structure and/or device that is capable of storing data, which is retrievable by a processor.

The communication controllers 1012 may be connected to the network 1014 (not a part of data processing system 1000) that may be any public or private data processing system network or combination of networks, as known to those of skill in the art, including the Internet. Data processing system 1000 may communicate over the network 1014 with one or more other data processing systems such as a server 1034 (also not part of the data processing system 1000). However, an alternative data processing system may correspond to a plurality of data processing systems implemented as part of a distributed system in which processors associated with a number of (e.g., several) data processing systems may be in communication via one or more network connections and may collectively perform tasks described as being performed by a single data processing system. Thus, it is to be understood that when referring to a data processing system, such a system may be implemented across several data processing systems organized in a distributed system in communication with each other via a network.

Further, the term “controller” may be any device, system, or part thereof that controls at least one operation, whether such a device is implemented in hardware, firmware, software, or some combination of at least two of the same. It should be noted that the functionality associated with any particular controller may be centralized or distributed, whether locally or remotely.

In addition, it should be appreciated that data processing systems may be implemented as virtual machines in a virtual machine architecture or cloud environment. For example, the processor 1002 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system may vary for particular implementations. For example, the data processing system 1000 in this example may correspond to a computer, workstation, server, PC, notebook computer, tablet, mobile phone, and/or any other type of apparatus/system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure. Also, it should be noted that the processor described herein may be located in a server that is remote from the display and input devices described herein. In such an example, the described display device and input device may be comprised in a client device that communicates with the server (e.g., and/or a virtual machine executing on the server) through a wired or wireless network (e.g., which may include the Internet). In some embodiments, such a client device, for example, may execute a remote desktop application or may correspond to a portal device that carries out a remote desktop protocol with the server in order to send inputs from an input device to the server and receive visual information from the server to display through a display device. Examples of such remote desktop protocols include Teradici's PCOIP, Microsoft's RDP, and the RFB protocol. In such examples, the processor described herein may correspond to a virtual processor of a virtual machine executing in a physical processor of the server.

As used herein, the terms “component” and “system” are intended to encompass hardware, software, or a combination of hardware and software. Thus, for example, a system or component may be a process, a process executing on a processor, or a processor. Additionally, a component or system may be localized on a single device or distributed across several devices.

Also, as used herein, a processor corresponds to any electronic device that is configured via hardware circuits, software, and/or firmware to process data. For example, processors described herein may correspond to one or more (or a combination) of a microprocessor, CPU, FPGA, ASIC, or any other integrated circuit (IC) or other type of circuit that is capable of processing data in a data processing system, which may have the form of a controller board, computer, server, mobile phone, and/or any other type of electronic device.

Those skilled in the art will recognize that, for simplicity and clarity, the full structure and operation of all data processing systems suitable for use with the present disclosure is not being depicted or described herein. Instead, only so much of a data processing system as is unique to the present disclosure or necessary for an understanding of the present disclosure is depicted and described. The remainder of the construction and operation of data processing system 1000 may conform to any of the various current implementations and practices known in the art.

Also, it should be understood that the words or phrases used herein should be construed broadly, unless expressly limited in some examples. For example, the terms “comprise” and “comprise,” as well as derivatives thereof, provide inclusion without limitation. The singular forms “a”, “an” and “the” are intended to include the plural forms as well, unless the context clearly indicates otherwise. Further, the term “and/or” as used herein refers to and encompasses any and all possible combinations of one or more of the associated listed items. The term “or” is inclusive, providing and/or, unless the context clearly indicates otherwise. The phrases “associated with” and “associated therewith,” as well as derivatives thereof, may provide to comprise, be comprised within, interconnect with, contain, be contained within, connect to or with, couple to or with, be communicable with, cooperate with, interleave, juxtapose, be proximate to, be bound to or with, have, have a property of, or the like.

Also, although the terms “first,” “second,” “third,” and so forth may be used herein to describe various elements, functions, or acts, these elements, functions, or acts should not be limited by these terms. Rather, these numeral adjectives are used to distinguish different elements, functions or acts from each other. For example, a first element, function, or act may be termed a second element, function, or act, and, similarly, a second element, function, or act may be termed a first element, function, or act, without departing from the scope of the present disclosure.

In addition, phrases such as “processor is configured to” carry out one or more functions or processes, may provide that the processor is operatively configured to or operably configured to carry out the functions or processes via software, firmware, and/or wired circuits. For example, a processor that is configured to carry out a function/process may correspond to a processor that is executing the software/firmware, which is programmed to cause the processor to carry out the function/process and/or may correspond to a processor that has the software/firmware in a memory or storage device that is available to be executed by the processor to carry out the function/process. It should also be noted that a processor that is “configured to” carry out one or more functions or processes may also correspond to a processor circuit particularly fabricated or “wired” to carry out the functions or processes (e.g., an ASIC or FPGA design). Further, the phrase “at least one” before an element (e.g., a processor) that is configured to carry out more than one function may correspond to one or more elements (e.g., processors) that each carry out the functions and may also correspond to two or more of the elements (e.g., processors) that respectively carry out different ones of the one or more different functions.

In addition, the term “adjacent to” may provide that an element is relatively near to but not in contact with a further element, or that the element is in contact with the further portion, unless the context clearly indicates otherwise.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computed-implemented method of engineering a physical system, the computed-implemented method comprising:
providing a set of first engineering artifacts and a set of second engineering artifacts of engineering information of the physical system;
determining a first annotation tree comprising first nodes representing the set of first engineering artifacts and determining a second annotation tree comprising second nodes representing the set of second engineering artifacts;
providing at least one ontology relating to the engineering information;
determining a respective similarity value of the respective first node and the respective second node using the respective ontology, wherein the respective similarity value depends on a respective distance between the respective first node and the respective second node in the respective ontology;
determining at least one of the first nodes that is related to at least one of the second nodes using the respective similarity value; and
generating a respective connector linking the respective first engineering artifact corresponding to the respective first node with the respective second engineering artifact corresponding to the related, respective second node.

2. The computer-implemented method of claim 1, wherein the set of first engineering artifacts comprises engineering information relating to physical information, a physical model, mechanical information, a mechanical model, electrical information, an electrical model, electronic information, an electronic model, hydraulic information, a hydraulic model, thermal information, a thermal model, control information, a control model, electric power information, an electric power model, process-oriented information, a process-oriented model, or any combination thereof of the physical system.

3. The computer-implemented method of claim 1, further comprising:
determining if the respective first engineering artifact is consistent with the connected, respective second engineering artifact; and
displaying a respective result of the determining of the consistency of the respective first engineering artifact with the connected, respective second engineering artifact to a user via an engineering user interface (UI);
storing the respective result of the determining of the consistency of the respective first engineering artifact with the connected, respective second engineering artifact in an engineering database; or
any combination thereof.

4. The computer-implemented method of claim 3, wherein the determining of the consistency of the respective first engineering artifact with the connected, respective second engineering artifact further comprises:
when the respective first engineering artifact and the connected, respective second engineering artifact comprise engineering information relating to a respective physical model, mechanical model, electrical model, electronic model, hydraulic model, thermal model, control model, electric power model, process-oriented model, or any combination thereof of the physical system,
determining if the respective model of the respective first engineering artifact is consistent with the respective model of the connected, respective second engineering artifact; or
when the respective first engineering artifact comprises engineering information relating to a respective physical model, mechanical model, electrical model, electronic model, hydraulic model, thermal model, control model, electric power model, process-oriented model, or any combination thereof of the physical system and the connected, respective second engineering artifact comprises lifecycle information relating to requirements, test cases, risks, hazards, uses cases, or any combination thereof of the physical system, determining if the model of the respective first engineering artifact is consistent with the requirements, test cases, risks, hazards, uses cases, or any combination thereof of the connected, respective second engineering artifact.

5. The computer-implemented method of claim 1, further comprising:
when the respective connector has been generated, producing the physical system according to the engineering information.

6. The computer-implemented method of claim 1, the method further comprising:
when the respective connector has been generated, engineering, modeling, simulating, analyzing, operating, controlling, or any combination thereof of the physical system using the engineering information.

7. The computer-implemented method of claim 3, further comprising:
displaying the respective first engineering artifact corresponding to the respective first node and the respective second engineering artifact corresponding to the related, respective second node to the user via the engineering UI;
capturing input of the user relating to an approval or a dismissal of generating the respective connector in response to user interactions with the engineering UI; and
generating the respective connector only upon the approval of the user of generating the respective connector.

8. The computer-implemented method of claim 7, further comprising:
displaying a list of at least one of the first engineering artifacts (122) corresponding to at least one of the first nodes and some of the second engineering artifacts corresponding to the related, respective second nodes to the user via the engineering UI, wherein the list is ordered with respect to the respective similarity values;
capturing the input of the user relating to a selection from the listed first engineering artifacts and second engineering artifacts and to an approval or a dismissal of generating the respective connector in response to user interactions with the engineering UI; and
generating the respective connector only upon the approval of the user of generating the respective connector.

9. The computer-implemented method of claim 1, further comprising:
determining the respective first node to be related to the respective second node when the respective similarity value exceeds a given similarity value threshold.

10. The computer-implemented method of claim 1, further comprising:
determining a respective weight of a respective node of the first nodes and the second nodes, wherein the respective weight is representative of the occurrence of the respective engineering artifact corresponding to the respective node in the engineering information; and
determining at least one of the first nodes that is related to at least one of the second nodes using the similarity value and further using the respective weight of the respective node.

11. The computer-implemented method of claim 10, wherein the respective node corresponds to a term or a phrase of at least two terms.

12. The computer-implemented method of claim 11, wherein a term-to-phrase-similarity value of the respective first node comprising one first term and the respective second node comprising one second phrase is a maximum among individual similarity values of a respective first term and second terms, and
wherein a phrase-to-phrase-similarity value of the respective first node comprising a first phrase and the respective second node comprising the second phrase is an average of the term-to-phrase-similarity value weighted with the respective weight of the respective first term and multiplied with a maximum among individual weights of the respective first terms.

13. A computer system comprising:
a processor configured to:
engineer a physical system, the processor being configured to engineer the physical system comprising the processor being configured to:
provide a set of first engineering artifacts and a set of second engineering artifacts of engineering information of the physical system;
determine a first annotation tree comprising first nodes representing the set of first engineering artifacts and determining a second annotation tree comprising second nodes representing the set of second engineering artifacts;
provide at least one ontology relating to the engineering information;
determine a respective similarity value of the respective first node and the respective second node using the respective ontology, wherein the respective similarity value depends on a respective distance between the respective first node and the respective second node in the respective ontology;
determine at least one of the first nodes that is related to at least one of the second nodes using the respective similarity value; and
generate a respective connector linking the respective first engineering artifact corresponding to the respective first node with the respective second engineering artifact corresponding to the related, respective second node.

14. (canceled)

15. A non-transitory computer-readable storage medium that stores instructions executable by one or more processors to engineer a physical system, the instructions comprising:
providing a set of first engineering artifacts and a set of second engineering artifacts of engineering information of the physical system;
determining a first annotation tree comprising first nodes representing the set of first engineering artifacts and determining a second annotation tree comprising second nodes representing the set of second engineering artifacts;
providing at least one ontology relating to the engineering information;
determining a respective similarity value of the respective first node and the respective second node using the respective ontology, wherein the respective similarity value depends on a respective distance between the respective first node and the respective second node in the respective ontology;
determining at least one of the first nodes that is related to at least one of the second nodes using the respective similarity value; and
generating a respective connector linking the respective first engineering artifact corresponding to the respective first node with the respective second engineering artifact corresponding to the related, respective second node.

16. The computer-implemented method of claim 2, wherein the set of second engineering artifacts comprises lifecycle information relating to conception information, requirements information, test cases information, risks information, hazards information, uses cases information, issues information, design information, realization information, service information, or any combination of the physical system.
